(19) United States
(12) Patent Application Publication
(10) Pub. No.: US 2008/0253090 A1
(43) Pub. Date: Oct. 16, 2008

(54) Ic Component Comprising a Cooling Arrangement

(75) Inventors: Christian Janisch, Burglengenfeld (DE); Karl Smirra, Wasserburg (DE)

Correspondence Address: LERNER GREENBERG STEMER LLP, P O BOX 2480, HOLLYWOOD, FL, 33022-2480, US

(73) Assignee: VDO AUTOMOTIVE AG, Regensburg (DE)

(21) Appl. No.: 12/089,668

(22) PCT Filed: Aug. 25, 2006
(86) PCT No.: PCT/EP2006/065694

§ 371 Date: Apr. 9, 2008

(30) Foreign Application Priority Data
Oct. 18, 2005 (DE) 10 2005 049 872.8

(51) Int. Cl. H05K 7/20

(52) U.S. Cl. 361/709

(57) ABSTRACT

An IC component has a cooling arrangement that is embodied as an electronic housing provided with a cooling body. The IC component is directly disposed on the cooling body in the electronic housing. The invention advantageously provides a cooling arrangement for IC components that enables the IC component to be efficiently and directly cooled and assembled in a simple manner, without requiring additional components. It is especially suitable for applications in electronic housings in the automotive field.

The invention relates to an IC component comprising a cooling arrangement, which is embodied as an electronic housing provided with a cooling body, especially for the automotive industry.

Because of the demands imposed under extreme operating conditions, an IC component, i.e. an electronic circuit carrier which does not feature an integrated cooling body, is subjected to heating not specified for it and not permissible for it. The impermissible heating up is the result of the environmental conditions, i.e. its mounting location and by self-heating from its own heat dissipation. The period of time, in which the temperature increase is present at the IC, normally lasts for several minutes. For this reason a solution is sought which for this short period removes the internal heat from the electronic circuit carrier or keeps the external heat away from it. The reason why additional expense is involved in removing the heat is the fact that the IC component is surrounded by epoxy resin with glass fiber and air and all of the said components are bad heat conductors. Even if heat-transfer compound, heat-transfer foil or similar is applied between housing and circuit board to expel the air, the circuit board itself has an insulating effect and only conducts the heat away very badly. The heat flow in the width, i.e. in the X and the Y direction below the circuit carrier is even worse than through the circuit board itself (Z direction).

There are current different solution paths being adopted to avert overheating of the circuit board.

A simple, yet still cost-effective solution, but one that is not very efficient as regards heat conductance, are small copper tubes (heatsink vias). These heatsink vias are positioned underneath the IC component through the circuit board and to a certain extent conduct the heat from the bottom of the IC component to the lower side of the circuit board. From here the thermal energy is given off to the housing by means of heat-transfer compound, heat-transfer foil or other air gap fillers. A good thermal connection is made between the IC cooling body and the circuit board and heatsink vias during the solder process using solder paste applied by screen printing. This concept provides the option in a simple manner and without additional manufacturing outlay of to a certain degree cushioning in a minor way the temperature spikes or overtemperatures which occur.

A more expensive option is the use of metal cores in the circuit board in the area of the electronic circuit carrier. The metal core is in most cases punched out of a copper sheet of circuit board thickness. In addition a recess in form of the metal core is made in the circuit board. The metal core is embedded by means of press-fit by the circuit board manufacturer at the surface height (flush) into the circuit board. This large copper mass allows relatively rapid removal of a large amount of heat through the circuit board thickness from the IC component via the heat-transfer compound or the heat-transfer foil to the housing. The housing ideally has good heat-conducting properties and is equipped with cooling fins. The basis of this metal inlay solution consists of soldering the IC component via its integrated cooling body to the circuit board. It thus obtains the ideal connection to the copper core so as to pass on the heat. Between the underside of the metal core and the circuit board is a slight shoulder. A larger shoulder is arranged between the upper side of the metal core and the circuit board. The gap thus produced between IC cooling body and metal inlay is filled by the solder paste applied by means of screen printing. The firm connection is then established in the soldering process.

One of the most expensive options in terms of construction as well as manufacturing and cost of removing the heat via the upper surface of the IC component consists of using elastic-plastic non-compressible heat-conducting pads (GAP pads). Since these pads should only be deformed by up to 25% and in this case a mounting and tolerance band of the installation point of appr. 1 mm has to be reckoned with, it is designed with a thickness of appr. 4 mm. This in its turn demands that this installation space is available and the forces arising in reshaping the heat-conducting pad during the installation of the circuit board and cover can be accepted, and the circuit board is not too greatly stressed or bent. This could otherwise lead to destruction of other electronic components, such as ceramic capacitors for example.

Using this as its starting point, the underlying object of the present invention is to create a cooling arrangement for IC components with an installation process which is as simple as possible to execute with few components which makes possible an efficient, direct cooling at the IC component.

This object is achieved by a cooling arrangement with the features of claim 1. Advantageous embodiments and developments, which can be used individually or in combination with one another, are the object of the dependent claims.

The outstanding aspect of the inventive cooling arrangement for IC components, which is embodied in the form of an electronic housing featuring a cooling body (e.g. cooling fins, cooling dome) is that the IC component is arranged directly on the cooling body in the electronic housing. To do this the insulating layer of air and circuit board around the IC component is broken, so that the electronic circuit carrier can be linked directly to the heat-conducting housing, which advantageously is made from aluminum. At the position of the IC component the circuit board preferably has a circular or rectangular recess within the IC leg connections. Through this opening the electronic housing is taken up to the IC component by means of a projection. In this case there is provision for the housing dome to have a sufficient gap from this opening cavity wall so that no overdetermination arises in the positioning or the mounting of the circuit board. This cavity in the circuit board can however also be used if required in suitable cases as a centering zero point by minimizing the gap to the housing dome. The gap required to make allowance for tolerances between IC component underside and housing dome tip is filled in the final assembly process with heat-transfer compound which forces out the insulating air. This connects the IC housing directly to the electronic housing and the heat can be removed via the cooling fins accommodated outside the electronic space into the environment.

During installation of the circuit board into the housing the IC component legs accept the forces arising from the sideways expulsion of the heat-transfer compound accumulating on the housing dome tip. To prevent this, the action of the circuit board installation force can be introduced by means of an insertion jig sitting on the upper side of the IC component via the IC housing to the heat-transfer compound. In this way the tensile forces acting on the IC component are taken up by its legs. Furthermore the forces acting against the circuit board installation direction which arise as a result of the expulsion of the heat-transfer compound can be reduced by optimizing the housing dome tip. Suitable housing dome tip profiling measures also reduce the distances to the IC component, which improved the heat conductance by enlarging the surface. The installation quality in this design compared to the prior art is improved by reducing the overall tolerance field size. One of the ways in which this is achieved is by a smaller number of tolerance bands in the tolerance chain.

The inventive cooling arrangement for IC components offers the advantage of an improved thermal conductivity which is also achieved by measures such as optimized profiling of the heat-conducting dome by increasing its surface. In addition air as an insulator can be excluded by the inventive arrangement. Between heat source and cooling body the number of components can be reduced by only having a thin blanket of heat-transfer compound between them. This makes a very efficient and rapid heat removal possible. An additional factor is that with the inventive cooling arrangement the design limitations can be reduced by the relatively large IC component height tolerance no longer having any effect with the present cooling arrangement. In respect of the production and assembly process there is the advantage of the costs being reduced by the relatively simple handling of the cooling arrangement. Thus the milling of the circuit board for creating the outer contour or the centering and alignment holes are already included in the production process. In the final assembly the incorporation of the heat-transfer compound between circuit board and housing is also already integrated or present.

It is preferable for the electronic housing to be made of a thermally-conductive material, such as aluminum for example, so that heat can be efficiently dissipated outwards. The aluminum cooling body exhibits the best thermal-transfer properties as regards the financial aspect by comparison with for example plastic housings. The cooling body can however also be made of other materials. It is also possible to mill it from a solid using cutting processes. Ideally however it should be produced using as casting process such as aluminum die casting or plastic injection molding for example.

It is advantageous for a circuit board supported between electronic housing and IC component to have a recess at the position of the IC component so that the IC component is in direct and extensive contact with the cooling body.

It is preferable for the electronic housing to feature a housing dome at the position of the IC component, which serves as a contact surface for the IC component. This housing dome enables direct contact between cooling element and IC component, without a further component, for example a support for the IC component having to be placed between them.

Preferably the IC component is connected by the heat-transfer compound to the housing dome, which, as a result of its thermal conductivity removes the heat from the IC component in the optimum manner.

It is also advantageous for the housing dome to have a contact surface with a profile for the IC component. The surface is enlarged by profiling of the contact surface. This contributes to better heat conduction and to a reduction of installation forces.

The present invention for the first time advantageously creates a cooling arrangement for IC components which make possible an efficient and direct cooling down of the IC component as well as a simple assembly without the need for additional components. Because of the increased temperature demands it is especially suitable for applications in electronic housings in the automotive industry.

Further advantages and embodiments of the invention will be explained below with reference to exemplary embodiments as well as with reference to the drawing.

The figures show the following schematic diagrams:

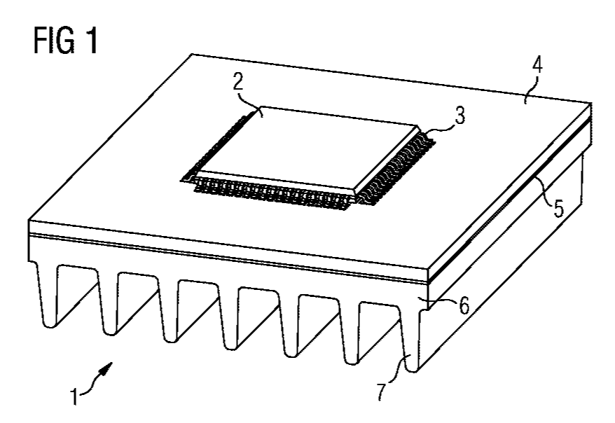

FIG. 1 a perspective view of an inventive cooling arrangement with IC component;

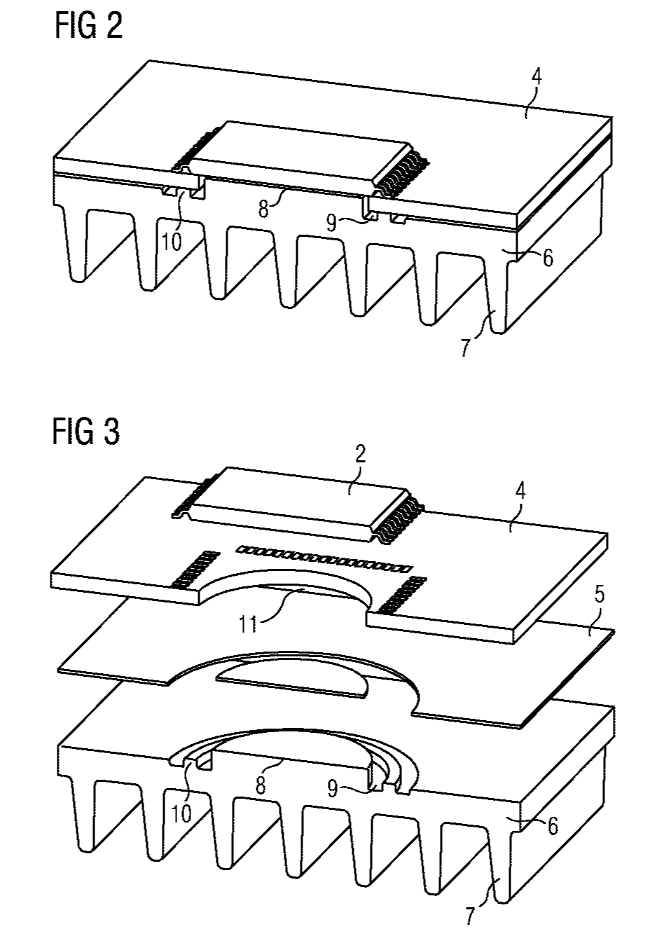

FIG. 2 a cross-sectional view of the inventive cooling arrangement with IC component;

FIG. 3 an exploded view of the cooling arrangement with IC component as depicted in FIG. 2;

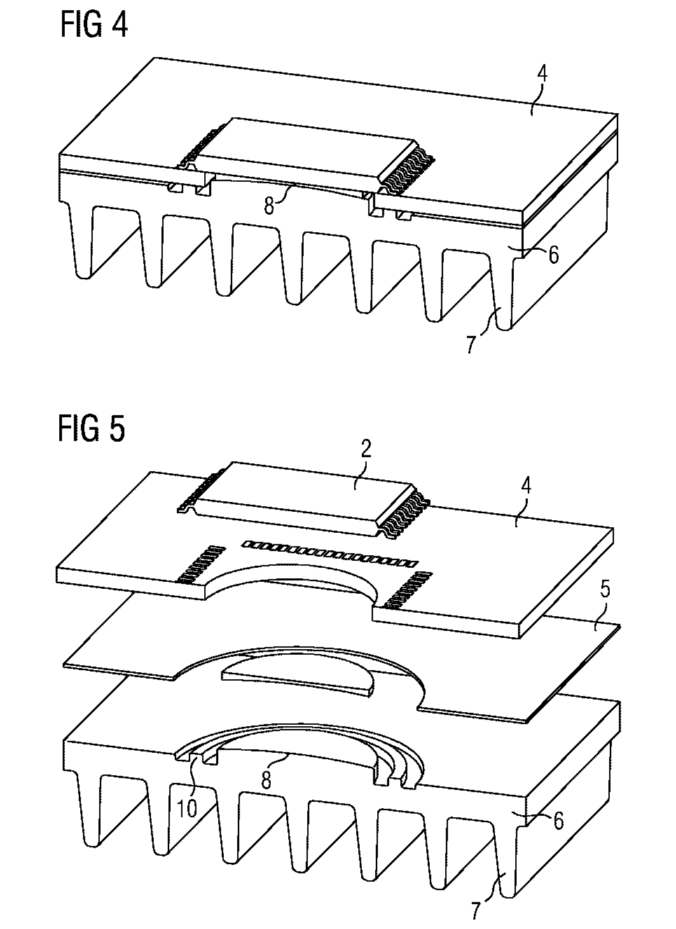

FIG. 4 a cross-sectional diagram of a second exemplary embodiment of the cooling arrangement with IC component;

FIG. 5 an exploded view of the cooling arrangement according to FIG. 4;

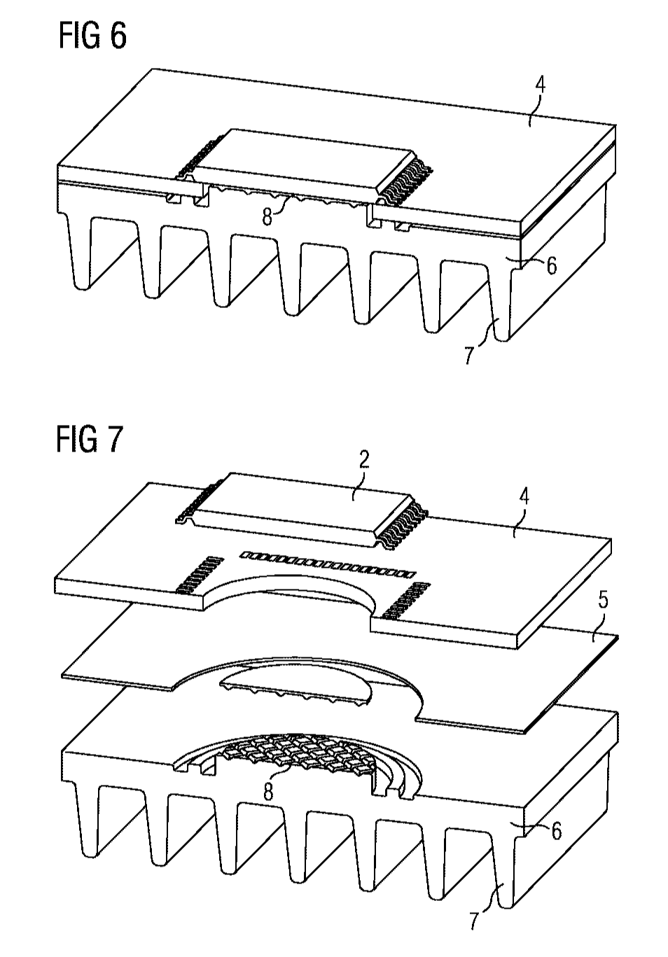

FIG. 6 a cross-sectional diagram of a third exemplary embodiment of the cooling arrangement with IC component;

FIG. 7 an exploded view of the cooling arrangement according to FIG. 6;

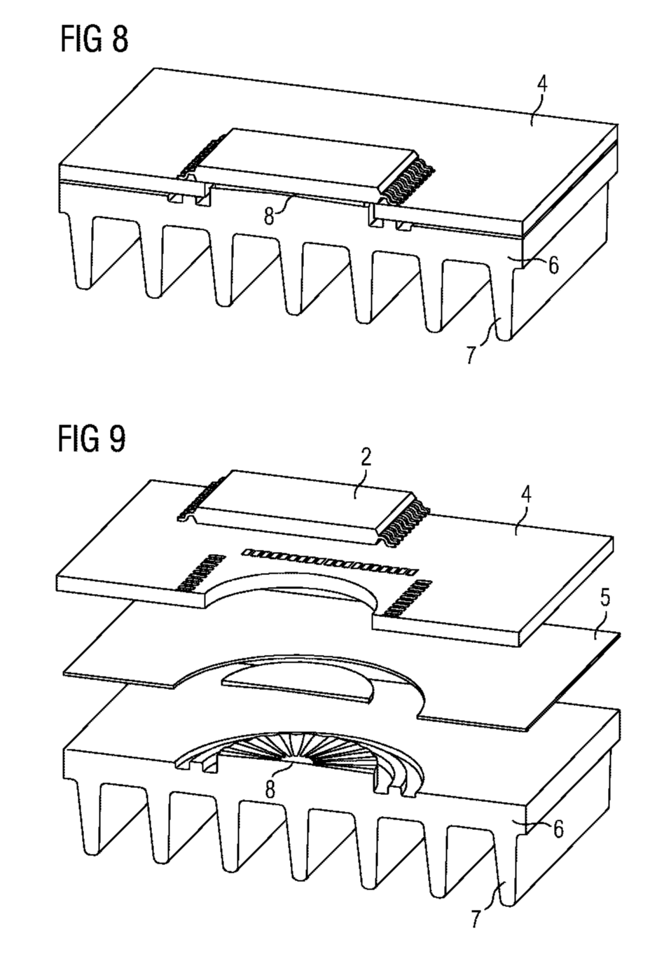

FIG. 8 a cross-sectional diagram of a fourth exemplary embodiment of the cooling arrangement with IC component;

FIG. 9 an exploded view of the cooling arrangement according to FIG. 8;

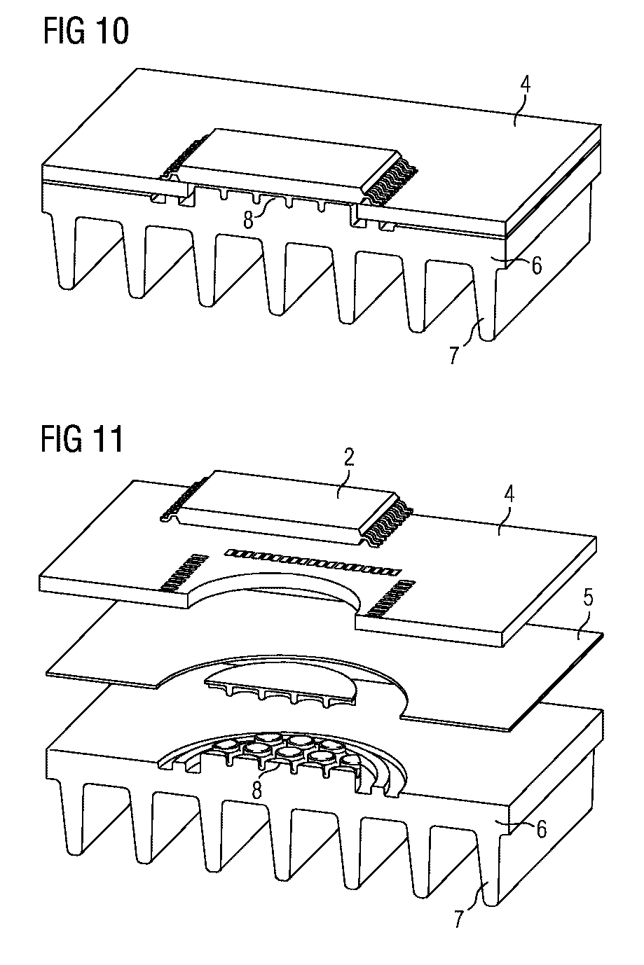

FIG. 10 a cross-sectional diagram of a fifth exemplary embodiment of the cooling arrangement with IC component;

FIG. 11 an exploded view of the cooling arrangement according to FIG. 10;

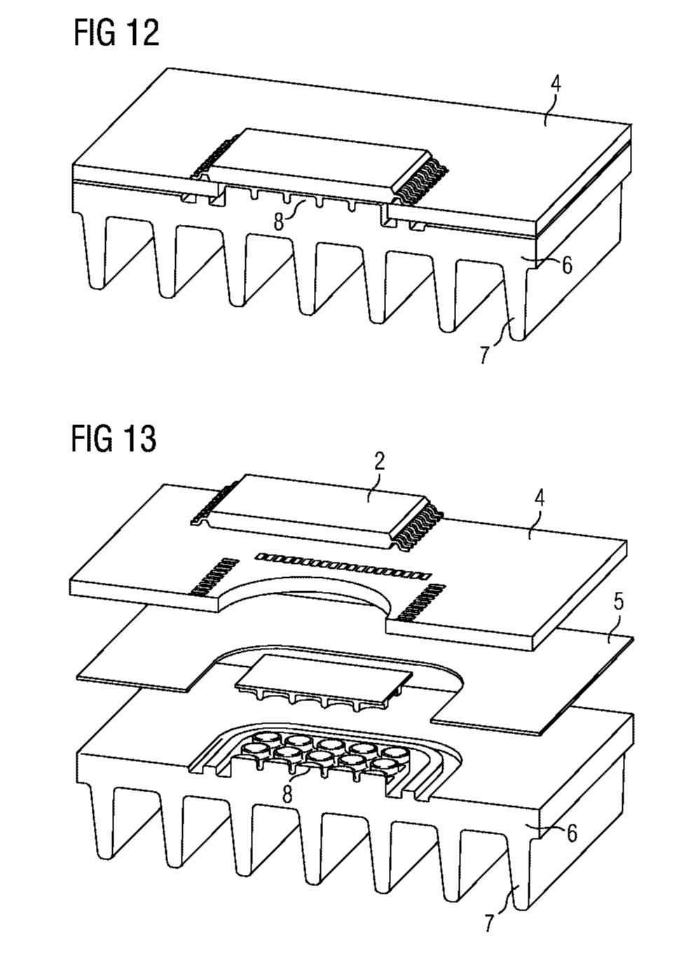

FIG. 12 a cross-sectional diagram of a sixth exemplary embodiment of the cooling arrangement with IC component and

FIG. 13 a cross-sectional view of the cooling arrangement according to FIG. 12;

FIG. 1 shows a perspective view of an inventive cooling arrangement 1 with IC component 2. The IC component 2 contacts a circuit board 4 via connecting legs and solder tin 3. The circuit board 4 is connected via a layer of heat-transfer compound 5 to a housing wall 6 which opens out into cooling fins 7.

FIG. 2 shows a cross-sectional view of the inventive cooling arrangement 1 with IC component 2. It can be seen from the cross-sectional diagram that the housing wall 6 at the position of the IC component 2 has a housing dome 8 with preferably a planar contact face which protrudes from the housing wall 6 and encloses the contact area of the IC component 2. The heat-transfer compound is present in the gap between dome and IC component as it is between PCB and housing. Furthermore the housing wall 6 preferably features two circular grooves 9 which are spaced from each other by a circular housing lip 10. The housing lip 10 is positioned so that the punched edge of the circuit board rests on the lip.

FIG. 3 shows in an exploded view of the cooling arrangement 1 with IC component 2, circuit board 4 and the layer of heat-transfer compound 5. The circuit board 4 preferably has a circular cutout 11 above which the IC component 2 is positioned. This makes it possible to bring the IC component 2 to be cooled into direct contact with the housing wall 6 or with the cooling body. To fasten the circuit board 4 and the IC component 2, a layer of heat-transfer compound 5 is applied to the contact face of the housing dome 8 as well as around the planar contact face around the grooves 10 of the housing wall 6.

FIG. 4 shows a cross-sectional view of the inventive cooling arrangement 1 with IC component 4. In this exemplary embodiment the housing dome 8 features a preferably concave contact face.

The exploded view in FIG. 5 shows a convex layer of heat-transfer compound 5 shaped to match the concave contact face of the housing dome 8.

FIG. 6 shows cross-sectional view in a further exemplary embodiment of the inventive cooling arrangement 1 with IC component 2, in which, as can be seen from the exploded view of FIG. 7 the contact face of the housing dome 8 preferably has cross-knurled-like profile. The layer of heat-transfer compound 5 on the housing dome 8 fills the gaps formed by the knurled profile and has a planar shape on the side facing the IC component 2.

FIG. 8 shows a cross-sectional diagram in a further exemplary embodiment of the inventive cooling arrangement 1 with IC component 2, with, as can be seen from the exploded view in FIG. 9, the contact face of the housing dome 8 is embodied by wedges preferably coming together to a point in two planes, of which the tips meet at the central point of the contact face. The layer of heat-transfer compound 5 resting on the housing dome 8 fills the gaps produced by the profile and lies planar on the IC component 2.

FIG. 10 shows cross-sectional view in a further exemplary embodiment of the inventive cooling arrangement 1 with IC component 2, in which, as can be seen from the exploded view of FIG. 11 the contact face of the housing dome 8 preferably has nap-shaped profile, with the distribution of the naps being similar to that of a Lego brick. The layer of heat-transfer compound 5 on the housing dome 8 fills the gaps formed by the nap-type profile and is embodied in a planar shape on the upper side facing towards the IC component 2.

FIG. 12 shows a cross-sectional diagram in a further exemplary embodiment of the inventive cooling arrangement 1 with IC component 2, with, as can be seen from the exploded view in FIG. 13, the contact face of the housing dome 8 preferably being formed into a rectangle. This leads to a likewise rectangular cutout in the circuit board 4 as well as to grooves 9 or a housing lip 10 embodied in a rectangular shape. In addition the rectangular implementation of the contact face of the housing dome 8 is also taken into account in the layer of heat-transfer compound 5.

The present invention advantageously creates for the first time a cooling arrangement 1 for IC components 2 which allows an efficient and direct cooling down of the IC component 2 as well as a simple assembly, without additional components being needed. It is especially suitable for applications in electronic housings in the automotive industry.

1-6. (canceled)

7. An assembly, comprising:
a cooling arrangement in the form of an electronic housing having a cooling body; and
an IC component disposed directly on said cooling body in said electronic housing.

8. The assembly according to claim 7 configured as an IC component for an automobile.

9. The assembly according to claim 7, wherein said electronic housing is formed of aluminum.

10. The assembly according to claim 7, which comprises a circuit board supported between electronic housing and said IC component, said circuit board having a recess formed therein at a position of said IC component.

11. The assembly according to claim 7, wherein said electronic housing comprises a housing dome formed at a position of said IC component.

12. The assembly according to claim 11, which comprises a heat-transfer compound connecting said IC component to said housing dome.

13. The assembly according to claim 11, wherein said housing dome is formed with a profiled contact face for contacting said IC component.

14. The assembly according to claim 7, wherein said IC component and said cooling body are disposed in mutual heat-transfer contact.
